(19) United States
(12) Patent Application Publication
(10) Pub. No.: US 2026/0164621 A1
(43) Pub. Date: Jun. 11, 2026

(54) Combined Heating and Cooling System for Residential Area and Data Center

(71) Applicants: Bradley John Klein, Chonburi (TH); Nicholas Ben Barrowclough, Porac (PH)

(72) Inventors: Bradley John Klein, Chonburi (TH); Nicholas Ben Barrowclough, Porac (PH)

(21) Appl. No.: 19/411,302

(22) Filed: Dec. 7, 2025

Related U.S. Application Data
(60) Provisional application No. 63/728,741, filed on Dec. 6, 2024.

(51) Int. Cl. H05K 7/20

(52) U.S. Cl. CPC H05K 7/20836; H05K 7/20763

(57) ABSTRACT

A combined heating and cooling system integrates a residential area and data center on a shared liquid circulation loop to improve overall thermodynamic efficiency. Rather than operating independently with narrow temperature ranges, the system arranges heat-exchange units in series, causing the circulating liquid to undergo a substantially larger temperature change of approximately 35° C. to 40° C. versus 15° C. to 25° C. in conventional systems. During summer cooling, liquid cooled by a common refrigeration unit sequentially passes through a residential air handling unit, then a data center air handling unit and coolant distribution unit, enabling the chiller to operate at higher efficiency. During winter, waste heat extracted from data center operations is captured and transferred via the liquid loop to heat the residential area, with a boiler deployed only as supplemental heat when necessary. An adaptive valve network accommodates mismatched flow requirements between the residential and data center portions. Temperature and flow sensors enable automatic switching between seasonal configurations. The system significantly reduces energy consumption for both heating and cooling by leveraging the broader temperature differential and recovering waste heat, delivering substantial operational cost savings and environmental benefits over the system's lifetime.

### CROSS-REFERENCE DATA

This patent application claims a priority date benefit from a U.S. Provisional Patent Application No. 63/728,741 filed on 6 Dec. 2025 with the same title, which is incorporated herein in its entirety by reference.

### BACKGROUND

Without limiting the scope of the invention, its background is described in connection with heating and/or cooling systems. More particularly, the invention describes a combined energy-efficient heating and/or cooling system configured to maintain a desired temperature range in a residential area and in a computer data center.

Heating, ventilation, and air conditioning (HVAC) systems are broadly known and widely used to maintain a desired residential temperature or temperature range in residential areas. For the purposes of this description, the term “residential area” includes any area where humans are expected to be present for an extended period of time, such as houses, apartment complexes, office space, commercial establishments, shopping malls, entertainment venues, and similar facilities. At the same time, similar liquid-based and air-based HVAC systems are used to maintain a desired data center temperature or temperature range in computer data centers, which house sensitive electronic equipment and servers that generate substantial operational heat. Conventionally, these systems are operated independently and do not overlap or share any heating or cooling elements, such as a common refrigeration unit, heating unit, heat exchangers, or liquid circulation loop.

HVAC systems consume a significant amount of energy and have long been a subject of continued improvement and optimization in order to maximize their energy efficiency and reduce operational costs. New configurations and designs in high-efficiency HVAC systems increasingly focus on smart technology, modularity, and environmentally friendly practices. Variable Refrigerant Flow (VRF) systems represent a popular advancement, allowing precise temperature control and energy efficiency by adjusting refrigerant flow to meet the demands of different zones. Geothermal heat pumps, which harness the Earth's stable underground temperatures, significantly reduce energy consumption compared to traditional air-source systems. Hybrid systems that combine traditional HVAC units with renewable energy sources, such as solar thermal collectors, also contribute to improved efficiency. Smart HVAC systems equipped with Internet of Things (IoT) devices enable real-time monitoring, predictive maintenance, and adaptive settings based on occupancy and weather conditions. Furthermore, designs incorporating energy recovery ventilation systems reuse waste heat or cooling to condition incoming air, thereby reducing energy waste. Advanced ductless systems, radiant heating and cooling panels, and natural ventilation integration in building designs are increasingly implemented to maximize energy savings and enhance overall sustainability.

Despite these improvements in performance, conventional HVAC systems remain designated to serve either residential areas or data centers, but not both. Each of these systems is typically designed to maintain a fairly narrow range of desired temperatures optimized for its specific application. For residential areas served by a liquid-air heat exchanger system, the desired temperature range of liquid entering the building air handling unit may fall between approximately 25° C. to 50° C. for heating during winter and approximately 10° C. to 15° C. for cooling during summer. For data centers, the desired temperature range of liquid entering the data center air handling unit and coolant distribution unit may fall between approximately 15° C. to 23° C. to cool the data center throughout the year, largely independent of the season.

Fundamental principles of thermodynamics teach that a heating or cooling system may be made more efficient if it has a broader range of temperatures between its inlet and outlet, thereby increasing the temperature lift across a refrigeration unit or heating unit. When a chiller or boiler is required to operate over a larger temperature differential, it can achieve higher coefficients of performance and lower specific energy consumption. Conversely, when a chiller or boiler is constrained to operate over a narrow temperature range—as is the case with conventional independent residential and data center HVAC systems—the system operates at reduced efficiency and consumes more energy to satisfy identical heating or cooling loads.

The conventional approach of deploying entirely separate HVAC systems for residential areas and data centers, therefore, represents a significant missed opportunity to improve overall energy efficiency. Each system is constrained to operate within a relatively narrow temperature band specific to its application, preventing the refrigeration unit and heating unit from leveraging the thermodynamic advantages offered by a broader temperature lift. Additionally, waste heat generated by data center operations, which can represent a substantial thermal resource, is conventionally rejected directly to the ambient environment via cooling towers or external heat exchangers, rather than being captured and reused to satisfy heating demands in an adjacent residential area.

A need exists, therefore, for an integrated heating and cooling system configured to serve both residential and data center areas on a common liquid circulation loop with higher overall energy efficiency compared to conventional independent systems. Such a system should leverage the different temperature requirements of residential and data center applications to increase the effective temperature lift across the refrigeration and heating units, enable recovery of waste heat from the data center for residential heating purposes, and accommodate practical scenarios in which the residential and data center portions have different flow rates and cooling or heating demands.

### SUMMARY

Accordingly, it is an object of the present invention to overcome these and other drawbacks of the prior art by providing a novel combined heating and cooling system to address the heating and cooling needs of a data center and a residential area nearby.

It is another object of the present invention to maximize energy efficiency for maintaining desired internal temperatures for both the data center and the residential area in different ambient environments.

The present invention relates to an energy-efficient, integrated heating and cooling system that combines a residential area and a data center on a common liquid circulation loop, thereby substantially improving the overall thermodynamic efficiency of both functions through strategic series arrangement, waste-heat recovery, and adaptive valve-based flow control. A “common liquid circulation loop” as used herein refers to a hydraulic arrangement in which thermal energy is transported along a continuous heat transfer path that serves both a residential area and a data center, and in which the fluid streams are either directly shared or indirectly coupled so that they behave as a single thermodynamic loop. In some embodiments, the common liquid circulation loop is implemented as a single piping circuit carrying one coolant stream that sequentially flows through a residential heat-exchange unit and a data center heat-exchange unit. In other embodiments, the common liquid circulation loop is implemented as two or more separate water circuits that are thermally coupled but hydraulically separated by at least one intermediate heat exchanger, such as a plate heat exchanger, so that the fluids in the different circuits do not mix while still exchanging heat across the plates. In such thermally coupled arrangements, the primary loop and secondary loop together are regarded as a common liquid circulation loop because heat is transferred between them in a manner that preserves the overall temperature profile and thermodynamic effect of the invention, including the increased temperature lift across the refrigeration unit and/or heating unit that results from serving both the residential area and the data center in series.

Conventional HVAC systems for residential areas and data centers operate independently, each with a narrow, fixed temperature range optimized for its respective use. Residential systems typically maintain liquid temperatures between 25° C. to 50° C. during heating and 10° C. to 15° C. during cooling, while data centers require liquid temperatures between 15° C. to 23° C. year-round. Because each system operates in isolation, the temperature differential available to a single chiller or boiler is limited, resulting in reduced thermodynamic efficiency and higher energy consumption. Fundamental principles of refrigeration and heating teach that these systems are more efficient when operated over a broader temperature lift, that is, when the difference between the inlet and outlet temperatures of the working fluid is maximized.

The conventional approach of deploying separate, independent HVAC systems for residential and data center applications, therefore, represents a missed opportunity. Each system is constrained to operate within a relatively narrow temperature band, forcing the refrigeration unit (chiller) and heating unit (boiler) to work harder and less efficiently than they could if they were allowed to operate over a wider range. This inefficiency translates directly into increased energy consumption and higher operating costs over the lifetime of the system.

The present invention overcomes this limitation by integrating the residential and data center systems on a shared liquid loop and arranging the heat-exchange units in series, so that the same circulating liquid sequentially passes through both the residential and data center heat-exchange stages. This arrangement causes the liquid to undergo a progressively larger temperature change, from its coldest state at the chiller outlet to its warmest state after exiting the data center cooling unit, thereby substantially increasing the temperature lift across the chiller and improving its overall coefficient of performance.

During summer cooling operation, the liquid cooled by a common refrigeration unit first passes through a residential air handling unit (AHU) to cool the building air, extracting heat and warming slightly. The now-warmer liquid then continues through a data center AHU and coolant distribution unit (CDU) to cool the data center air and equipment, extracting additional heat and warming further. This sequential arrangement means the chiller must cool the return liquid not only to the residential cooling temperature but further still to account for the additional heat extracted from the data center. The net effect is a temperature differential of roughly 35° C. to 40° C., which is substantially larger than the 15° C. to 25° C. typical of single-purpose conventional systems, thereby enabling the chiller to operate at significantly higher efficiency.

During winter heating operation, the arrangement is adapted so that heat extracted from data center operations (which generate substantial waste heat during normal operation) is transferred via the liquid loop to heat the residential area. Rather than rejecting data center heat to ambient and simultaneously operating a boiler to generate heat for the residence, the present invention captures the data center waste heat and redirects it for heating purposes. A boiler is deployed only as a supplemental source when data center waste heat alone is insufficient to meet residential heating demands, thus dramatically reducing boiler runtime and energy consumption.

The invention further includes an optional external heat exchanger (referred to in the specification as the “preFree” unit) positioned between the data center CDU exit and the chiller inlet. This external heat exchanger allows the system to leverage ambient air cooling, particularly effective during nighttime hours when ambient temperatures are cooler. By pre-cooling the return liquid before it reaches the chiller, the system can significantly reduce or eliminate mechanical chiller operation during favorable ambient conditions, further reducing energy consumption.

A practical challenge in combining the two systems is that the residential area and data center may have different cooling and heating flow rate requirements. For example, a large residential building may require more liquid flow than a smaller data center can utilize, or conversely, a high-density data center may require more cooling flow than the residential area provides. The invention addresses these scenarios through a network of control valves and sensors that intelligently route liquid flow based on real-time demand.

When residential flow demand exceeds data center demand during cooling, excess flow from the residential AHU can be routed directly back to the chiller via a bypass valve, allowing the system to continue operating efficiently without forcing excess flow through the data center. Conversely, when data center demand exceeds the flow provided by the residential AHU, supplemental chilled water from the chiller can be introduced directly into the data center circuit via another bypass valve, ensuring adequate cooling of electronic equipment without requiring the residential area to generate unnecessary cooling flow.

Additionally, within the data center itself, the AHU and CDU may have different flow characteristics and cooling requirements. The AHU typically handles larger volumes of air at lower temperatures, while the CDU handles smaller volumes of liquid at higher temperatures. The invention includes valve arrangements that allow a portion of liquid exiting the AHU to bypass the CDU and return directly to the chiller or external heat exchanger, accommodating these differences and preventing flow bottlenecks.

The system automatically switches between distinct operational configurations based on ambient conditions and the season. During summer, the controller activates the refrigeration unit and arranges valves to achieve the series cooling configuration described above. During winter, the controller reconfigures the valves to enable heat recovery from the data center and activates the boiler only when necessary. The system may also operate in a hybrid mode where the data center receives free cooling via the external heat exchanger while the residential area continues to use mechanical refrigeration if ambient conditions do not provide sufficient cooling for both functions simultaneously.

The invention includes a suite of temperature and flow sensors distributed throughout the liquid circulation loop. These sensors continuously monitor conditions at key points: at the chiller outlet, at the inlet and outlet of each heat exchanger, and in the return line. A controller processes this sensor data and adjusts valve positions and the on/off status of the chiller and boiler to maintain desired temperature setpoints and to respond to changes in load and ambient conditions. The controller may also be programmed to recognize the current date or to detect a significant change in ambient temperature and to automatically transition between seasonal configurations.

The invention further contemplates that the residential area and data center are located close to one another. Ideally, they are located within the same building, such as an office building with a data center in the basement or a residential apartment complex with a data center facility on the premises. This co-location minimizes the length of pipes required for the liquid circulation network, reducing heat loss and pumping energy. The invention is not limited to a single residential area and single data center; multiple data centers can be served in parallel from the same common chiller and boiler by deploying multiple CDU branches in the hydraulic network, each with its own AHU and CDU. Similarly, multiple residential zones or buildings can be connected to the common system if conditions warrant.

Overall, the present invention provides a practical, hardware-implemented solution to improve the energy efficiency of combined residential and data center HVAC systems through intelligent series arrangement, waste-heat recovery, and adaptive flow control. The invention delivers substantial operational cost savings and environmental benefits over the lifetime of the system by reducing overall energy consumption for both heating and cooling functions.

### BRIEF DESCRIPTION OF THE DRAWINGS

Subject matter is particularly pointed out and distinctly claimed in the concluding portion of the specification. The foregoing and other features of the present disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings, in which:

FIG. 1 is a block diagram showing a combined cooling system for a residential area and a data center, wherein liquid cooled by a common refrigeration unit flows sequentially through a residential air handling unit and then through a data center air handling unit and coolant distribution unit.

FIG. 2 is a block diagram showing a combined residential heating and data center cooling system, wherein liquid circulates first through a data center air handling unit and coolant distribution unit to extract waste heat, and then through a residential air handling unit to transfer that heat for residential heating purposes, with a boiler deployed as a supplemental heating source.

FIG. 3 is a block diagram showing an exemplary configuration of the combined system with a plurality of valves, pipes, sensors, a pump, a refrigeration unit, and a heating unit, illustrating a summer operational configuration wherein cooling water is directed to circulate through the residential area and then the data center.

FIG. 4 is a block diagram showing the combined system in a summer configuration with excess water flow from the residential air handling unit, wherein bypass valves are opened to direct excess water directly back to the refrigeration unit while bypassing the data center portion.

FIG. 5 is a block diagram showing the combined system in a summer configuration wherein water flow circulating through the residential air handling unit is insufficient for data center cooling purposes, and supplemental water from the refrigeration unit is introduced into the data center portion via open valves.

FIG. 6 is a block diagram showing the combined system in a summer configuration wherein water flow through the data center air handling unit is too high for the coolant distribution unit, and bypass valves direct a portion of water from the data center air handling unit directly toward the external heat exchanger or refrigeration unit, bypassing the coolant distribution unit.

FIG. 7 is a block diagram showing the combined system in a winter configuration wherein warm water from the data center is insufficient to provide adequate residential heating, and valves are opened to introduce supplemental hot water directly from the boiler into the residential air handling unit.

FIG. 8 is a block diagram showing the combined system in a winter configuration wherein water flow from the data center is too high for residential heating needs, and bypass valves direct a portion of the water flow to bypass the residential air handling unit and enter the exit portion of the residential circuit.

FIG. 9 is a block diagram showing the combined system in a summer configuration wherein ambient air temperature is cold enough to provide sufficient cooling for the data center via an external heat exchanger, but the refrigeration unit is operated to provide cooling for the residential area.

FIG. 10 is a block diagram showing the combined system configured with multiple data center cooling branches positioned in parallel, each comprising a data center air handling unit and coolant distribution unit, all served by a common refrigeration unit and heating unit.

FIG. 11 shows a summer configuration of the system using a liquid-to-liquid heat exchanger.

FIG. 12 shows a winter configuration of the system using the liquid-to-liquid heat exchanger.

### DETAILED DESCRIPTION OF PREFERRED EMBODIMENTS OF THE INVENTION

The following description sets forth various examples along with specific details to provide a thorough understanding of claimed subject matter. It will be understood by those skilled in the art, however, that claimed subject matter may be practiced without one or more of the specific details disclosed herein. Further, in some circumstances, well-known methods, procedures, systems, components and/or circuits have not been described in detail in order to avoid unnecessarily obscuring claimed subject matter. In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

The present invention provides a combined heating and cooling system that integrates a residential area and a data center on a common liquid circulation loop to achieve higher energy efficiency than conventional independent systems. The invention leverages the different temperature requirements of residential and data center applications to increase the temperature lift across a refrigeration unit and heating unit, enabling more efficient operation while recovering waste heat from the data center for residential heating purposes.

### System Architecture and Components

The combined system includes a common liquid circulation loop that circulates a coolant liquid, such as water, throughout the system. The loop is fluidly connected to a first heat-exchange unit configured to exchange heat between the liquid and air of the residential area, and a second heat-exchange unit configured to exchange heat between the liquid and at least one of air and electronic equipment of the data center. In preferred embodiments, the first heat-exchange unit is a residential air handling unit (AHU) in fluid communication with air of an office building, commercial establishment, or residential apartment building, and the data center is located within the same building or in a basement of the building.

The second heat-exchange unit comprises a data center air handling unit configured to exchange heat between the liquid and data center air, and a coolant distribution unit (CDU) configured to exchange heat between the liquid on a facility side and a coolant on an equipment side, the coolant being circulated proximate to electronic equipment of the data center. The CDU regulates and circulates cooling water between heat-generating sources such as computer servers and a heat rejection system, and may feature a high-efficiency heat exchanger that isolates the facility water loop from the equipment cooling loop to ensure compatibility and prevent cross-contamination. The CDU is configured to monitor and adjust key parameters such as flow rate, temperature, and pressure to maintain optimal cooling performance.

A refrigeration unit is configured to reduce the temperature of the liquid on the common liquid circulation loop, providing chilled water for cooling purposes. A heating unit, such as a boiler, is configured to increase the temperature of the liquid on the common liquid circulation loop, providing hot water for heating purposes. The heating unit is optional and is actuated only when the heat extracted from the data center is insufficient to satisfy the heating demand of the residential area.

The system further includes a plurality of valves and pipes configured to direct the liquid sequentially through the first heat-exchange unit and the second heat-exchange unit. A controller is operatively coupled to the valves and is configured to operate the valves to establish different flow configurations for cooling mode and heating mode. The controller receives input from temperature sensors disposed at a plurality of locations along the common liquid circulation loop and flow sensors associated with at least one of the first heat-exchange unit and the second heat-exchange unit, and operates the valves responsive to signals from these sensors.

### Operation in Cooling Mode (Summer Configuration)

In a cooling mode, the controller operates the valves in a summer configuration wherein the refrigeration unit is active, and the heating unit is inactive. Liquid cooled by the refrigeration unit to a first temperature, preferably between about 10° C. to about 15° C., is circulated through the building AHU to cool the residential area. As the liquid extracts heat from the building air, its temperature increases to a second temperature, preferably between about 15° C. to about 23° C. This warmer liquid is then directed to the data center AHU, which extracts heat from data center air and transfers that heat into the liquid, further warming the liquid to a third temperature, preferably between about 20° C. to about 35° C. The liquid then flows to the CDU, which extracts additional heat from electronic equipment, warming the liquid to a fourth temperature, preferably approaching about 50° C. After exiting the CDU, the high-temperature water is directed back toward the refrigeration unit to complete the circulation loop.

The system may include an external heat exchanger (referred to as a “preFree” unit) located outside a building enclosing at least one of the residential area and the data center. The external heat exchanger is configured to transfer heat between the liquid on the common liquid circulation loop and ambient air. The controller is configured to selectively route the liquid through the external heat exchanger prior to the refrigeration unit to pre-cool the liquid when the ambient air temperature is below the temperature of the liquid exiting the CDU. This allows the system to reduce the water temperature to approximately the ambient air temperature without expending energy to run the refrigeration unit, which is particularly advantageous during nighttime when ambient air is cooler. After this initial cooling stage, the liquid is directed to the refrigeration unit where it is cooled further to the temperature suitable for use at the inlet of the building AHU.

In some embodiments, the common liquid circulation loop is implemented as a single hydraulic circuit in which the same liquid sequentially flows through the principal heat-exchange units. In a summer configuration, liquid cooled by the refrigeration unit flows from the chiller outlet to the first heat-exchange unit associated with the residential area, where it absorbs heat from residential air, and then continues to the second heat-exchange unit associated with the data center, where it absorbs additional heat from data center air and electronic equipment. After passing through these units in series, the warmed liquid returns toward the inlet of the external heat exchanger and/or back to the refrigeration unit, thereby completing a single, continuous circulation loop that serves both the residential area and the data center in sequence.

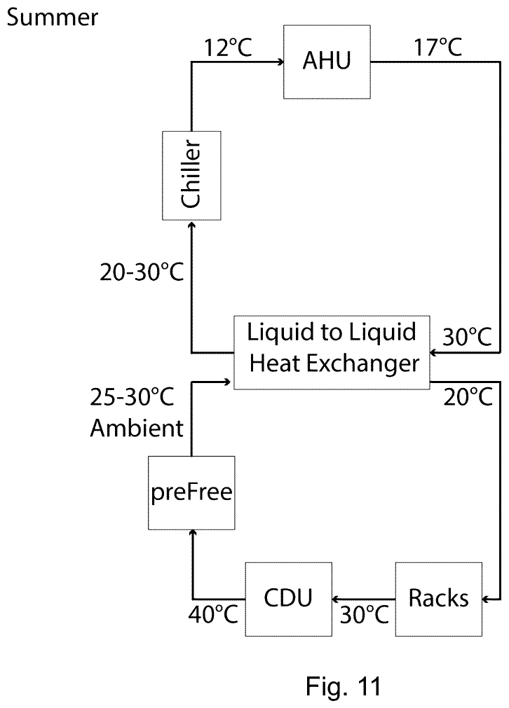

In other embodiments, the common liquid circulation loop is implemented using thermally coupled but hydraulically separate liquid circuits. In such arrangements, a primary circuit includes the refrigeration unit and at least one primary-side heat exchanger, for example a plate heat exchanger, while a secondary circuit includes the first and second heat-exchange units serving the residential area and the data center in series. Liquid cooled by the refrigeration unit circulates within the primary circuit and transfers heat across the common liquid-to-liquid heat exchanger into the liquid circulating in the secondary circuit—see FIG. 11. From a thermodynamic standpoint, the primary and secondary circuits together behave as a common liquid circulation loop because heat is transferred between them in a manner that preserves the overall temperature profile and temperature lift associated with sequentially serving the residential and data center loads.

### Operation in Heating Mode (Winter Configuration)

In a heating mode, the controller operates the valves in a winter configuration wherein heat extracted from the data center by the second heat-exchange unit is transferred via the liquid to the first heat-exchange unit to heat the residential area. The liquid circulates first through the data center AHU and CDU to extract waste heat from data center operations, warming the liquid to a first elevated temperature, preferably approaching about 50° C. The controller compares the temperature of the liquid after the CDU to a heating threshold. When the first elevated temperature is below the heating threshold, the controller actuates the heating unit to further heat the liquid to a second elevated temperature sufficient for residential heating. The heated liquid is then directed through the building AHU to warm up air and water circulated throughout the residential area. The water temperature at the exit of the building AHU drops as heat is transferred to the residential area. If the water temperature is low enough, it may be directed back into the data center AHU. If it is not sufficiently cooled, it may be circulated through the optional external preFree unit to use ambient air cooling to reduce the water temperature back to a level suitable for air cooling the equipment of the data center.

A similar concept to that described above for the summer configuration applies in winter configurations. In some embodiments, a single hydraulic circuit is arranged so that liquid first exchanges heat with the data center via the second heat-exchange unit, thereby extracting waste heat from data center operations, and then flows to the first heat-exchange unit to deliver that heat into the air of the residential area. The heating unit, such as a boiler, is controlled so that it is actuated only when the temperature of the liquid leaving the second heat-exchange unit falls below a predetermined heating threshold. In this way, the system preferentially uses recovered data center heat for residential heating and supplements it with boiler heat only when necessary.

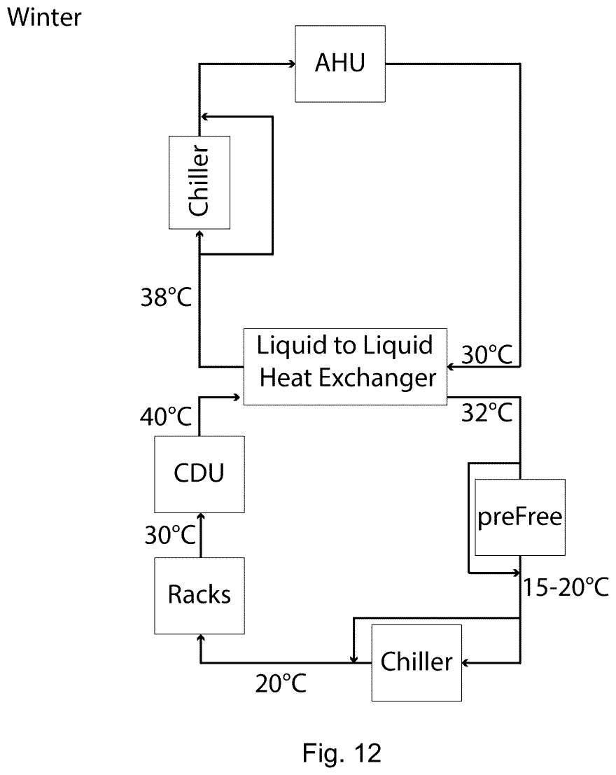

In other winter embodiments, the common liquid circulation loop is realized by thermally coupling two or more circuits through at least one intermediate heat exchanger. For example, a secondary circuit serving the data center AHU and CDU transfers heat into a primary circuit that also communicates with the residential heat-exchange unit and the heating unit. Although the liquids in the primary and secondary circuits do not mix, heat transfer across the intermediate liquid-to-liquid heat exchanger establishes an effective temperature progression from the data center to the residential area that is analogous to that of a single-circuit loop—see FIG. 12. In all such cases, the thermally coupled circuits are configured so that the combined operation maintains the desired temperature profile between the data center and residential portions, thereby preserving the thermodynamic benefits of the invention, including increased temperature lift across the refrigeration unit and/or heating unit and improved overall energy efficiency.

### Handling Mismatched Flow Requirements

The system is configured to accommodate scenarios where the flow of liquid required by the residential area does not match the flow required by the data center. During the cooling mode, when the flow required by the residential area exceeds the flow required by the data center, the controller operates at least one valve to route excess liquid from the building AHU directly toward the external heat exchanger or refrigeration unit while bypassing at least a portion of the data center portion of the system.

Conversely, when the flow required by the data center exceeds the flow provided by the building AHU, the controller operates at least one valve to introduce supplemental liquid from a discharge of the refrigeration unit toward the data center AHU while bypassing the building AHU. This ensures adequate cooling of the data center regardless of upstream flow conditions.

Within the data center portion, when the flow of liquid required by the data center AHU exceeds the flow permissible through the CDU, the controller operates at least one valve to route a portion of the liquid from the data center AHU directly toward the external heat exchanger or refrigeration unit while bypassing the CDU. This prevents overloading of the CDU and maintains optimal cooling performance across both the air-cooling and liquid-cooling portions of the data center.

### Free Cooling Configuration

The controller is configured to operate the valves to route liquid from the CDU through the external heat exchanger and then back to an inlet of the data center AHU to provide free cooling to the data center when the ambient air temperature is sufficiently low to satisfy the data center cooling load. In this configuration, the refrigeration unit may be deactivated for the data center portion while remaining active for the building AHU if the ambient air temperature is not low enough to satisfy the residential cooling load.

### Control System and Automatic Mode Switching

The controller is configured to automatically switch between the winter configuration and the summer configuration based on at least one of the present calendar date and sensor input. The sensor input may include detecting a temperature change in ambient air exceeding a preset winter/summer threshold, or other sensor input, such as temperature sensors indicating the heating or cooling load of the residential area or data center. The controller receives signals from the temperature sensors and flow sensors and actuates the plurality of valves and at least one of the refrigeration unit and the heating unit to establish the appropriate flow configuration.

### Data Center Sub-combination

A separate aspect of the invention provides a data center portion of a combined residential and data center heating and cooling system, comprising a data center AHU, a CDU, a liquid circulation path fluidly connecting an outlet of the AHU to an inlet of the CDU such that liquid flows sequentially from the AHU to the CDU, and a valve network configured to selectively bypass at least a portion of one of the AHU and the CDU when a flow demand of the other unit exceeds a predetermined threshold. The valve network comprises a first bypass valve disposed downstream of the AHU and upstream of the CDU, configured to route a portion of liquid from the AHU directly away from the CDU when the flow through the AHU exceeds the flow capacity of the CDU, and a second bypass valve disposed upstream of the AHU, configured to introduce supplemental liquid from an external source into the liquid circulation path when the flow demand of the CDU exceeds the flow provided by the AHU. This ensures adequate cooling of both the data center air and the electronic equipment, regardless of upstream flow conditions.

In all embodiments, the system may be scaled to serve multiple data centers or multiple residential areas by positioning additional cooling or heating branches in parallel, all served by the same common refrigeration unit and heating unit. Each branch may include suitable numbers of water circulation components, sensors, and valves as described above, allowing the system to accommodate varying sizes and specific heating or cooling demands of different facilities.

The invention thus provides a comprehensive solution for efficiently heating and cooling both residential areas and data centers by integrating them on a common liquid circulation loop, leveraging sequential heat exchange, waste heat recovery, and intelligent flow control to achieve superior energy efficiency compared to conventional independent systems.

### Exemplary Configurations

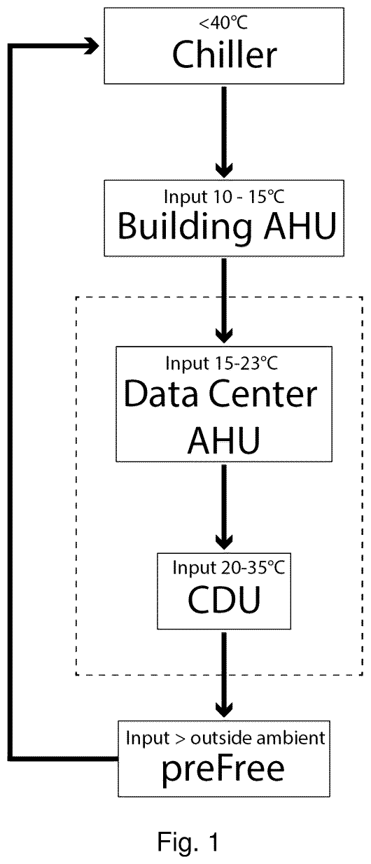

FIG. 1 is a block diagram illustrating the combined cooling system during summer operation. The system includes a common liquid chiller that provides coolant liquid at a temperature lower than about 40° C. The liquid exits the chiller at approximately 10° C. to 15° C. and enters the building AHU, where it extracts heat from residential air. After passing through the building AHU, the liquid temperature rises to approximately 15° C. to 23° C. This warmer liquid then enters the data center AHU, which extracts heat from data center air and transfers that heat into the liquid, further warming it to approximately 20° C. to 35° C. The liquid then flows to the CDU, which removes additional heat from electronic equipment, warming the liquid further. High-temperature water exiting the CDU may be directed back to the chiller or may first pass through a “preFree” external heat exchanger that uses ambient air to pre-cool the water before it reaches the chiller, reducing chiller energy consumption.

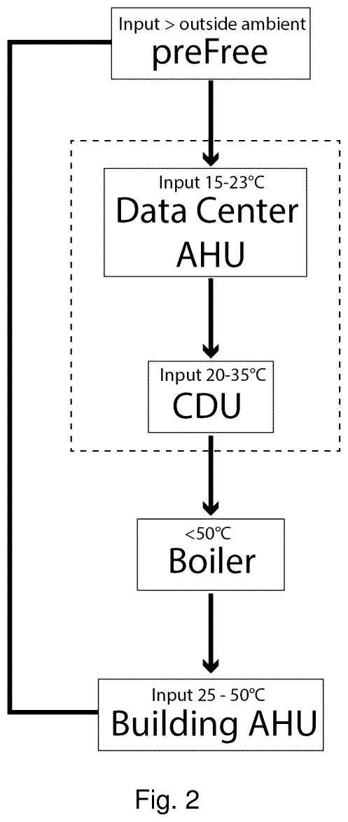

FIG. 2 is a block diagram illustrating the combined residential heating and data center cooling process during winter operation. The system circulates water that may have its lowest temperature at the exit of the building AHU or at the exit of the preFree unit, at approximately 15° C. to 23° C. This cooled water is first circulated through the data center AHU to extract heat from computer equipment, warming the water to approximately 20° C. to 40° C. The warmer water then passes through the CDU, which extracts additional heat, raising the temperature further to approximately 50° C. If the water temperature is below the level required for residential heating, a boiler is activated to supplement the heating. Hot water from the boiler is directed to the building AHU to warm residential air and water. After exiting the building AHU, the water temperature drops and is either directed back to the data center AHU or circulated through the optional preFree unit to reduce its temperature to a level suitable for cooling data center equipment.

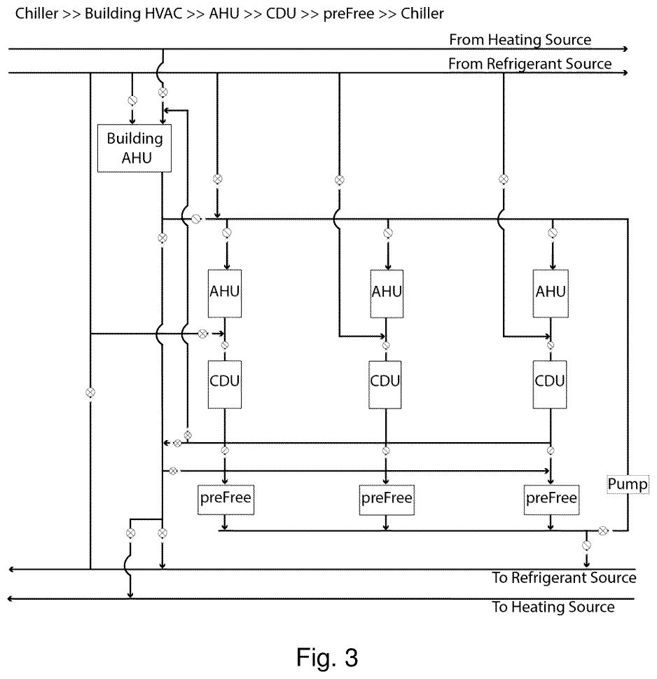

FIG. 3 is a block diagram showing an exemplary configuration that combines both cooling and heating concepts into a single system. The configuration includes two main lines at the top of the diagram: one providing hot water from the heating source and one providing cooling water from the chiller. Only one of these lines is operational, depending on the season. The bottom of the diagram shows two return lines: one returning water to the refrigeration system or chiller for summer use, and another returning water to the heater or boiler for winter use. The system includes a plurality of water flow and temperature sensors (not shown) to detect the performance of various heat exchangers. A variety of ON/OFF and adjustable valves are positioned throughout the water circulation network to direct, adjust, or cut off water flows. A pump is provided to cause water flow throughout the pipe network based on valve positions. The specific valve positions shown in FIG. 3 illustrate a summer configuration where cooling water circulates according to the sequence shown in FIG. 1.

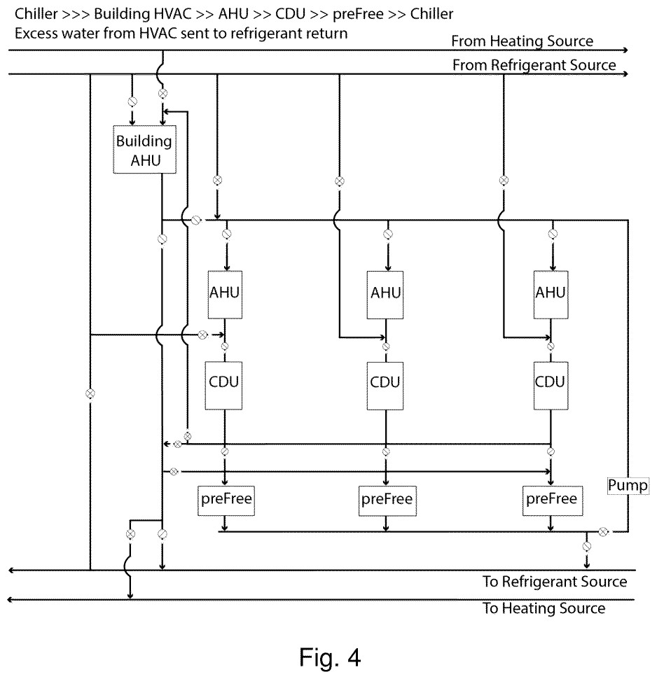

FIG. 4 is a block diagram showing a summer configuration of the combined heating and cooling system where the water flow required for cooling the building AHU exceeds the water flow required for the data center portion. This scenario occurs when the residential area is significantly larger than the data center and is therefore “mismatched” to the data center in terms of cooling demand. For example, a large office building or residential complex may require substantially more cooling capacity than a smaller data center located within the same facility.

In this configuration, the refrigeration unit operates to cool liquid to approximately 10° C. to 15° C., and the cooled liquid enters the building AHU with the expectation that the residential area will consume a particular flow rate of cooling water. However, when the residential area is larger, the cooling demand may require more water flow than the data center can accept downstream. Rather than restricting flow or creating pressure imbalances in the system, the present invention accommodates this mismatch through intelligent valve positioning.

Specifically, valves disposed in the water circulation network downstream of the building AHU and upstream of the data center AHU are at least partially opened to create a bypass path. A portion of the cooled water exiting the building AHU, after extracting heat from the residential area and being warmed to approximately 15° C. to 23° C., is routed directly back toward the refrigeration unit or external heat exchanger, bypassing the data center portion of the system entirely. The remaining portion of the water flow continues through the data center AHU and CDU at a flow rate that is compatible with the data center cooling requirements.

This configuration offers several advantages. First, it prevents the creation of excessive back-pressure in the data center cooling circuit, which could reduce heat transfer efficiency or damage equipment. Second, it ensures that the data center receives appropriate flow rates for optimal thermal management without over-sizing or unnecessarily cooling its systems. Third, the bypass water that returns directly to the chiller still carries heat extracted from the residential area, allowing the chiller to operate over a wider temperature range and thus more efficiently, even though not all the return water passes through the data center. The controller monitors flow rates and temperatures throughout the system using flow sensors and temperature sensors, and actuates the bypass valves to maintain the appropriate balance between residential and data center flows.

This scenario is particularly common in mixed-use facilities such as office buildings with data centers in the basement, where the office space occupies substantially more area and generates greater cooling demand than the data center. By allowing excess flow to bypass the data center, the system remains operationally flexible and maintains energy efficiency across a wide range of building configurations and cooling demands.

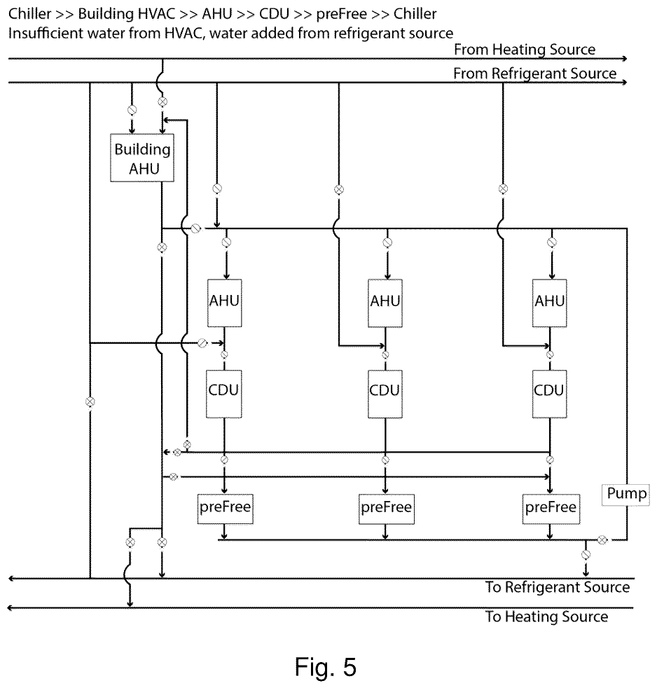

FIG. 5 is a block diagram showing a summer configuration of the combined heating and cooling system where the water flow circulating through the building AHU is insufficient to satisfy the cooling demand of the data center portion. This scenario occurs when the residential area is significantly smaller than the data center and is therefore “mismatched” to the data center in terms of cooling capacity. For example, a small office building or residential complex may have a modest cooling requirement that is substantially less than the cooling demand imposed by a large, high-density data center located within the same facility.

In this configuration, the refrigeration unit operates to cool the liquid to approximately 10° C. to 15° C. The cooled liquid enters the building AHU, where it extracts heat from the residential area and exits warmed to approximately 15° C. to 23° C. This water then flows to the data center AHU, where it begins to extract heat from data center equipment. However, the quantity of water flow available from the building AHU is insufficient to remove all the heat generated by the data center servers and other electronic equipment. The data center cooling demand exceeds the supply of cooling water provided by the residential portion of the system.

To address this mismatch, valves disposed in the water circulation network upstream of the data center AHU are at least partially opened to create a supplemental flow path. Additional chilled water directly from the discharge of the refrigeration unit, at approximately 10° C. to 15° C., is introduced into the data center cooling circuit in parallel with the water flowing from the building AHU. This supplemental chilled water combines with the warmer water from the building AHU, and the blended flow proceeds through the data center AHU and CDU at a flow rate that matches the data center cooling requirements.

This configuration provides several important benefits. First, it ensures that the data center receives adequate cooling water flow to maintain electronic equipment within acceptable temperature ranges and prevent thermal stress or operational shutdown. Second, the supplemental chilled water maintains overall system temperature balance, preventing the data center from becoming a bottleneck that starves the data center of the cooling capacity it requires. Third, the system maintains the benefit of waste heat recovery by still routing the warmer water from the building AHU through the data center, allowing that heat to be extracted and contributing to the overall temperature rise across the chiller. The additional chilled water from the refrigeration unit supplements this flow without disrupting the series arrangement or heat recovery benefits of the integrated system.

The controller monitors flow rates at the inlet and outlet of the data center AHU using flow sensors and temperature sensors, and actuates the supplemental flow valves to ensure that the combined flow rate through the data center portion meets or exceeds the data center cooling demand while maintaining appropriate temperature profiles. This scenario is common in facilities where data center capacity has grown over time or where a large data center has been integrated into a smaller residential building. By allowing supplemental chilled water to be introduced directly into the data center circuit, the system remains operationally flexible and capable of supporting high-density data center cooling requirements regardless of the size of the residential component.

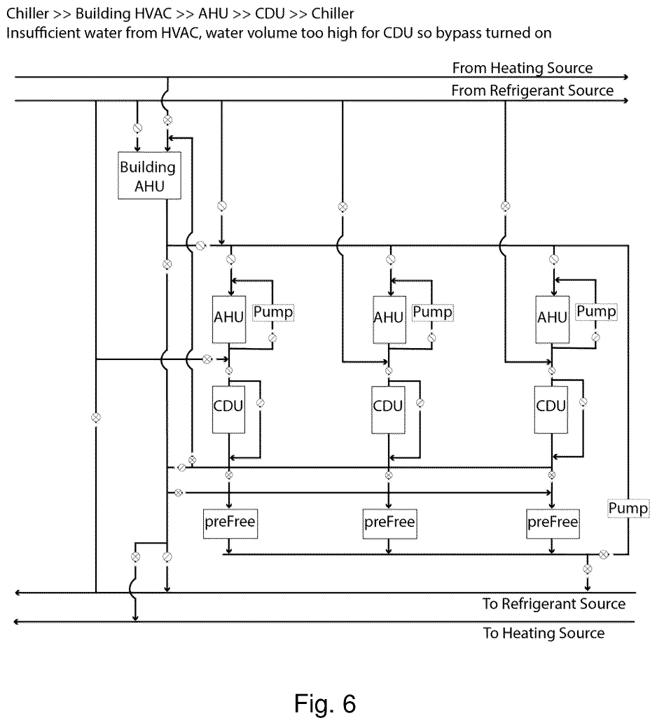

FIG. 6 is a block diagram showing a summer configuration of the combined heating and cooling system that addresses a more complex flow mismatch scenario. In this configuration, the water flow circulating through the building AHU is insufficient for data center cooling purposes, as described in the context of FIG. 5. However, FIG. 6 depicts an additional complication: the water flow through the data center AHU, after being supplemented by additional chilled water from the refrigeration unit, becomes too high for the CDU portion of the data center cooling system to accommodate.

This scenario arises when the data center architecture incorporates both air-cooled and liquid-cooled cooling strategies with fundamentally different flow rate requirements. The data center AHU typically handles large volumes of air at relatively modest temperature changes and can accommodate substantial water flow rates. In contrast, the CDU, which circulates cooling water through or near electronic equipment in a direct-to-chip or immersion cooling configuration, may be designed for significantly lower flow rates. When supplemental chilled water is introduced to satisfy air-cooling demands in the data center AHU, the total flow through the data center AHU may exceed what the CDU can effectively process.

To accommodate this mismatch, valves disposed downstream of the data center AHU and upstream of the CDU are at least partially opened to create a bypass path around the CDU. A portion of the water exiting the data center AHU, after extracting heat from data center air, is routed directly away from the CDU and returned to the external preFree heat exchanger or directly to the common refrigeration unit. This bypass water carries heat that has been extracted from data center air, contributing to the overall temperature rise across the system and allowing the chiller to benefit from a broader temperature differential.

The remaining portion of the water flow continues through the CDU at a flow rate that is compatible with the liquid-cooling architecture and heat-transfer performance specifications of the CDU. This ensures that the CDU receives only the flow rate it is designed to handle, preventing pressure spikes, flow maldistribution, or damage to sensitive cooling loops and equipment connections.

This configuration introduces additional operational flexibility to the system. By allowing excess flow from the data center AHU to bypass the CDU, the system can support scenarios where data center cooling demand cannot be satisfied by the building AHU and residential area alone, yet the CDU has physical or design limitations on maximum flow rate. The controller monitors flow rates at multiple points using flow sensors positioned at the outlet of the data center AHU, at the inlet and outlet of the CDU, and in the bypass path. The controller actuates the bypass valves to maintain appropriate flow distribution between the CDU and the bypass path, ensuring that the CDU operates within its design specifications while satisfying overall data center thermal management requirements.

This scenario is particularly common in hybrid data center cooling systems that combine traditional air-cooled and modern liquid-cooled approaches to manage power density and cost. By intelligently routing excess flow around the CDU while maintaining adequate cooling for both air-cooled and liquid-cooled portions of the data center, the system achieves optimal thermal management and energy efficiency even in complex, heterogeneous data center environments.

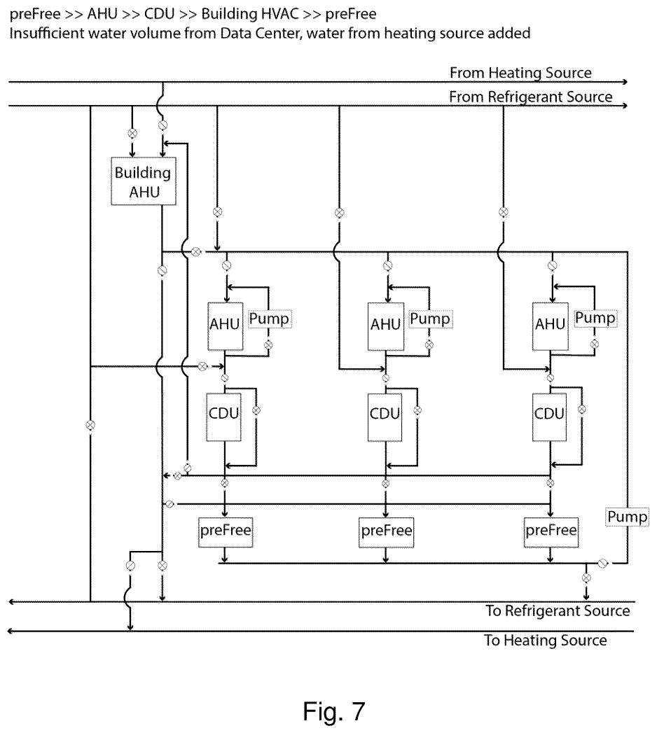

FIG. 7 is a block diagram showing a winter configuration of the combined heating and cooling system where waste heat recovered from data center operations is insufficient to satisfy the heating demand of the residential area. This scenario occurs when the data center generates less waste heat than the residential area requires for space heating and domestic hot water, or when ambient conditions or data center workload are such that the available waste heat falls below the heating setpoint required by the residential facility.

In this configuration, the system operates in heating mode as described previously, with liquid circulating first through the data center AHU and CDU to extract waste heat from data center operations. The heat generated by computer servers, cooling systems, and other equipment warms the circulating liquid to a first elevated temperature, typically approaching approximately 50° C. This warmed liquid is then directed to the building AHU to transfer heat into the residential area and warm the indoor air and potable water systems.

However, in some circumstances, the quantity of waste heat available from the data center may be less than the heating demand of the residential area. This may occur during periods of reduced data center utilization, when computational loads are low and equipment generates less thermal output. Alternatively, it may occur during mild winter weather when the data center's waste heat alone provides close to the required setpoint but falls slightly short. In such cases, relying solely on data center waste heat would result in residential space temperatures dropping below comfort levels or hot water setpoints being undersatisfied.

To address this heating deficiency, the boiler is activated and operated to supplement the heating capacity provided by the data center. Valves disposed in the water circulation network between the boiler and the building AHU are opened to introduce hot water from the boiler directly into the building AHU circuit. This supplemental hot water combines with and augments the warmer water flowing from the data center, raising the combined liquid temperature to a level sufficient to satisfy residential heating requirements.

The controller monitors temperature at multiple locations in the system, including at the outlet of the data center CDU and at the inlet of the building AHU, using temperature sensors. When the controller determines that the temperature of water exiting the data center CDU falls below a heating threshold required by the residential area, the controller actuates the boiler to activate and begins opening boiler outlet valves to introduce supplemental hot water. The controller may modulate the position of these valves or operate the boiler at a variable output to introduce only the quantity of supplemental heat necessary to reach the desired residential heating setpoint, thereby minimizing boiler energy consumption and operating cost.

This configuration provides several advantages. First, it allows the system to continue leveraging data center waste heat for the majority of the residential heating load, reducing reliance on the boiler and significantly lowering energy consumption compared to conventional systems that would operate the boiler continuously during winter. Second, it provides a fail-safe mechanism to ensure residential comfort is maintained even if data center operations fluctuate or ambient conditions change unexpectedly. Third, the boiler is operated only when necessary to supplement insufficient waste heat, rather than operating independently to satisfy the entire residential heating load.

This scenario is particularly common during winter months when data center utilization may vary significantly, or in facilities where data center operations have been downsized or consolidated. By allowing the boiler to be deployed as a supplemental heating source rather than as the primary heat source, the system achieves substantial energy savings and environmental benefits over the lifetime of the facility.

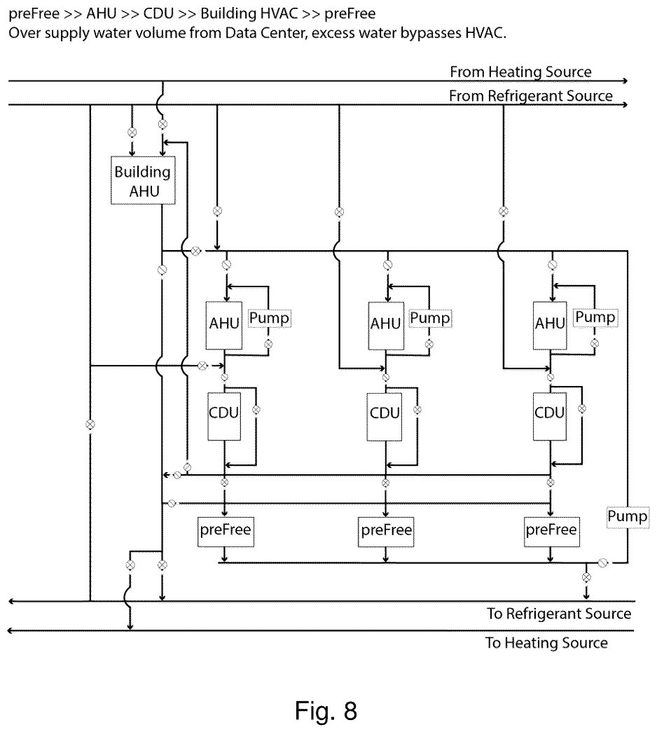

FIG. 8 is a block diagram showing a winter configuration of the combined heating and cooling system where the water flow coming from the data center is too high for the residential heating requirements. This scenario occurs when the data center generates more waste heat or requires more circulation flow than the residential area can accept for heating purposes. This mismatch may arise when a large, actively operating data center is paired with a smaller residential facility, or when data center operations are at peak capacity while residential heating demand is relatively modest due to mild outdoor temperatures or reduced occupancy.

In this configuration, the system operates in heating mode with liquid circulating through the data center AHU and CDU to extract waste heat. The warmed liquid exiting the data center CDU at approximately 50° C. or higher is directed toward the building AHU to transfer heat into the residential area. However, the quantity of warm water flow generated by the data center exceeds what the building AHU can effectively utilize for residential heating purposes. If all of this excess flow were forced through the building AHU, the system would rapidly elevate residential indoor temperatures above comfort levels and heating setpoints, creating thermal discomfort and wasting energy.

To address this flow mismatch, valves disposed in the water circulation network downstream of the data center CDU and upstream of the building AHU are at least partially opened to create a bypass path. A portion of the warm water exiting the data center CDU is routed to bypass the building AHU entirely and directed instead to the exit portion of the building AHU circuit, rejoining the return path to the data center. The remaining portion of the warm water continues through the building AHU at a flow rate that matches the residential heating demand and capacity of the building AHU.

This bypass configuration provides several important operational benefits. First, it prevents thermal overshoot in the residential area, maintaining indoor temperatures at the desired setpoint without excessive heating that would trigger air conditioning systems or degrade occupant comfort. Second, it allows the data center cooling loop to continue circulating at appropriate flow rates to remove the heat generated by data center equipment, preventing thermal buildup in the data center itself. Third, the bypass path enables the system to maintain stable loop pressures and flow dynamics without creating backpressure or flow restrictions that could compromise data center cooling performance.

The controller monitors flow rates and temperatures throughout the system using flow sensors positioned at the outlet of the data center CDU, at the inlet and outlet of the building AHU, and in the bypass path. The controller also receives temperature setpoint input from a residential thermostat or building management system. Based on these inputs, the controller actuates the bypass valves to modulate the flow split between the building AHU and the bypass path. If residential heating demand increases, the controller reduces bypass valve opening to direct more warm water through the building AHU. If residential heating demand decreases, the controller increases bypass valve opening to redirect more warm water away from the building AHU.

In some embodiments, the warm water that bypasses the building AHU may be routed through the optional external preFree heat exchanger before returning to the data center cooling loop. This allows the system to reject excess data center heat to ambient air during winter, leveraging cooler outdoor temperatures to reduce the effective heat load that must be managed by the data center cooling systems. Alternatively, the bypass water may be directed directly back to the data center inlet if external cooling is not needed or available.

This scenario is common in facilities where data center capacity substantially exceeds residential heating requirements, such as office buildings or apartment complexes with undersized data centers, or facilities where data center workload and heat generation vary significantly throughout the day. By allowing excess warm water from the data center to bypass the residential heating circuit, the system maintains optimal thermal management of both the data center and residential area while preventing energy waste and ensuring occupant comfort.

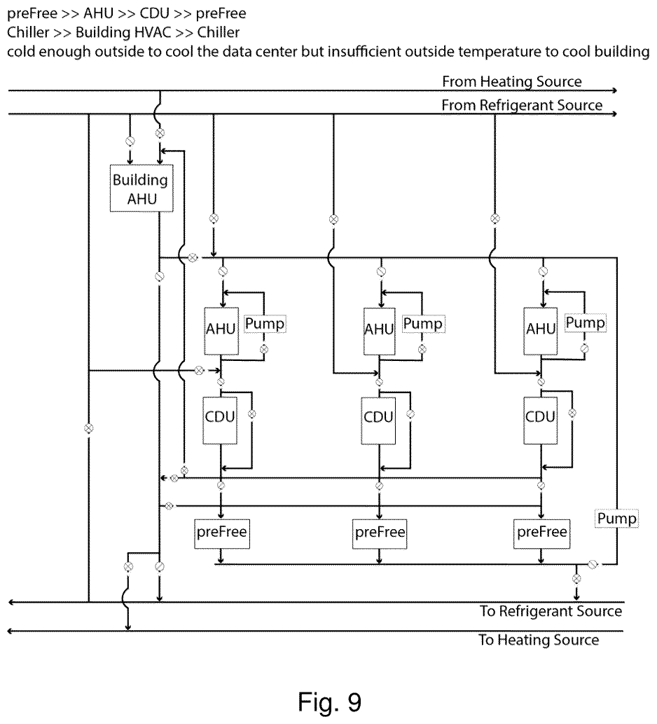

FIG. 9 is a block diagram showing a summer configuration of the combined heating and cooling system that exploits differential ambient conditions to optimize energy efficiency. In this scenario, ambient air temperature is sufficiently cold to provide adequate heat extraction for cooling data center equipment via the external preFree heat exchanger, but the ambient air temperature is not cold enough to satisfy the more stringent cooling requirements of the residential area. This configuration commonly occurs during early morning or late evening hours during summer months, or in geographic regions with cool ambient air even during daytime summer conditions.

In conventional systems, the refrigeration unit would operate continuously to satisfy both residential and data center cooling demands regardless of ambient conditions. However, the present invention enables a more sophisticated operational strategy by decoupling the residential and data center cooling circuits and routing them through different heat-rejection pathways based on real-time ambient conditions.

In this configuration, the controller monitors ambient air temperature using sensors positioned outside the building or facility. When the controller determines that ambient air temperature has fallen to a level suitable for data center free cooling (typically between approximately 10°C. to 15° C.), the controller reconfigures the system valves to implement a specialized cooling mode. The data center AHU and CDU are isolated from the main refrigeration unit, and instead, warm water exiting the data center CDU is routed directly to the external preFree heat exchanger. In the preFree unit, heat is transferred from the circulating liquid to the ambient air without requiring any mechanical refrigeration. The cooled liquid exiting the preFree heat exchanger is then recirculated back to the inlet of the data center AHU at a temperature suitable for extracting additional heat from data center equipment.

This free-cooling pathway allows the data center to operate at full cooling capacity using only the ambient air temperature and the passive heat transfer capabilities of the external heat exchanger, consuming substantially less energy than would be required by a mechanical refrigeration unit. The preFree operation may be further optimized by modulating a fan associated with the external heat exchanger to increase air flow and heat transfer rate when ambient temperatures are particularly cold, or by reducing fan speed when ambient conditions are marginal to minimize parasitic energy consumption.

Simultaneously, the residential area continues to require cooling because ambient air temperature alone is insufficient to cool the residential space to comfortable levels. The controller maintains the refrigeration unit in an active state and routes chilled liquid from the refrigeration unit directly to the building AHU. The residential cooling circuit operates independently of the data center cooling circuit, with liquid cooled to approximately 10° C. to 15° C. flowing through the building AHU to extract heat from residential air and maintain comfort levels. The warmer liquid exiting the building AHU may be routed back to the refrigeration unit for re-cooling, or may be directed to the preFree unit if additional ambient cooling benefit can be extracted.

This dual-pathway configuration provides several significant advantages. First, it dramatically reduces energy consumption compared to conventional systems by leveraging free cooling from ambient air for the data center while still maintaining adequate cooling for the residential area. The refrigeration unit operates only for the residential cooling load rather than for both loads, substantially reducing compressor runtime and electricity consumption. Second, this configuration is particularly effective during shoulder seasons (spring and fall) when ambient temperatures fluctuate around the threshold needed for data center cooling, allowing the system to transition between free cooling and mechanical cooling modes dynamically as conditions change.

The controller manages the transition between operating modes by continuously monitoring ambient air temperature and comparing it to predefined thresholds. As ambient air temperature rises above the data center free-cooling threshold, the controller gradually increases the flow of liquid through the refrigeration unit while reducing the preFree flow until the system transitions to conventional cooling mode with all liquid flowing through the refrigeration unit. Conversely, as ambient air temperature drops below the threshold, the controller gradually shifts data center cooling load from the refrigeration unit to the preFree unit until free cooling is fully engaged. This gradual transition prevents thermal shock and maintains stable temperature control throughout the system.

This scenario is particularly valuable in facilities located in moderate climates or at higher elevations where ambient air temperature can be cool even during summer months. Data centers in such locations can achieve substantial energy savings by operating in free-cooling mode during portions of the year when ambient conditions permit. By allowing the residential area to continue receiving mechanical refrigeration while decoupling it from data center cooling, the system maintains occupant comfort while maximizing the efficiency gains available from ambient conditions.

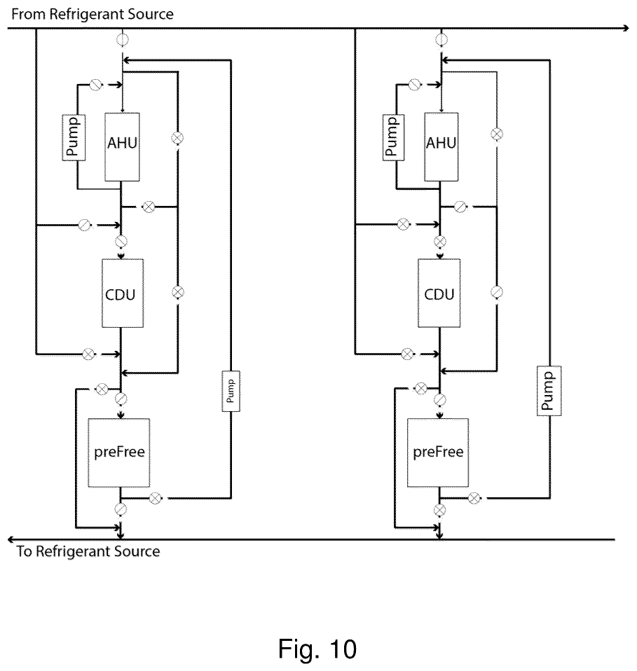

Finally, FIG. 10 is a block diagram illustrating the scalability and modularity of the combined heating and cooling system by depicting a configuration where multiple data center cooling branches are positioned in parallel, all served by a single common refrigeration unit and heating unit. This architecture allows the system to support facilities with multiple data centers, multiple independently operated sections or zones within a large data center, or a mix of data centers and residential areas, all while benefiting from the efficiency gains of the integrated common loop approach.

In this configuration, each data center branch comprises its own data center AHU and CDU, fluidly connected in series as described in the context of the single-data-center configurations. However, rather than each data center having its own dedicated refrigeration unit and heating unit, all data center branches draw chilled liquid from a single common refrigeration unit positioned upstream. Similarly, all data center branches return warm liquid to a common return path that feeds back to the refrigeration unit or external preFree heat exchanger.

Each data center branch includes its own set of control valves, flow sensors, and temperature sensors to enable independent operation and thermal management. The controller receives sensor inputs from each branch and operates the valves associated with each branch independently to accommodate different cooling demands, flow rate requirements, and thermal characteristics of each data center or data center zone. For example, if one data center branch requires greater cooling flow than another due to higher computational density or equipment loading, the controller can open the bypass valves associated with that branch to introduce additional chilled liquid from the refrigeration unit while simultaneously restricting flow to lower-demand branches.

This parallel architecture provides several significant advantages. First, it enables substantial cost savings by allowing multiple data centers or data center zones to share a single large, high-efficiency refrigeration unit rather than each requiring its own dedicated chiller. A larger, centralized chiller typically operates more efficiently than multiple smaller chillers, and the shared approach reduces capital equipment costs and footprint requirements.

Second, the common refrigeration unit benefits from a broader aggregate temperature lift because heat from all data center branches contributes to raising the return liquid temperature before it reaches the chiller inlet. This wider temperature differential enables the chiller to operate at higher efficiency even when individual branches may have moderate cooling demands.

Third, the parallel architecture provides operational flexibility and redundancy. If one data center branch requires maintenance or experiences reduced operational demand, the system continues to provide cooling to the other branches without interruption. The controller can modulate the bypass valves and supplemental flow paths to redistribute cooling capacity as needed. If temporary cooling demand spikes occur in one branch while other branches have lower demand, the system can route additional chilled liquid to the high-demand branch while maintaining adequate cooling for all facilities.

Fourth, the system can accommodate data centers with heterogeneous characteristics and requirements. One data center branch may require air-cooled only cooling, while another may employ a hybrid approach with both air-cooled and liquid-cooled components. One branch may have stringent temperature control requirements (e.g., ±2°C. tolerance), while another may tolerate broader temperature ranges (e.g., ±5°C.). The independent valve and sensor configuration for each branch allows the controller to tailor cooling delivery to the specific requirements of each data center.

In embodiments where the facility includes both residential areas and multiple data centers, the residential cooling or heating may also benefit from this parallel architecture. During winter heating mode, waste heat from all data center branches contributes to a common warm return path that feeds heat to the residential area via the building AHU. If residential heating demand is high, the system can route all available waste heat from all data center branches to the building AHU. If residential heating demand is lower, the system can modulate the distribution of data center waste heat to the residential area and the external preFree unit, or can direct excess heat back to the data centers if needed.

The controller manages the parallel configuration through a coordinated control algorithm that monitors total system conditions and individual branch conditions. The algorithm may prioritize cooling delivery based on facility criticality (e.g., ensuring full cooling to primary data centers first), based on historical load patterns (e.g., anticipating peak demand and pre-cooling before demand spikes), or based on real-time operational status (e.g., responding to equipment alarms or thermal alerts). The controller may also implement load-balancing logic to distribute chiller load evenly across multiple data center branches to promote uniform wear and extend equipment life.

In some embodiments, the parallel architecture extends to multiple refrigeration units or heating units, with each unit sized and optimized for a particular subset of data center branches or residential areas. This approach allows for even greater scalability and provides enhanced redundancy, as the loss of one refrigeration or heating unit does not compromise the entire facility. The controller manages distribution of flow and heat among multiple chillers or boilers using valve positioning and load-balancing algorithms.

A similar arrangement may be provided for using the same boiler for heating purposes across more than one residential area and/or more than one data center. In such configurations, each residential area or data center branch includes its own building AHU or data center heating circuit, all connected in parallel to a common heated return path fed by a single boiler. The controller modulates valve positions and boiler output to distribute heat among the various branches based on individual heating demand and setpoint requirements.

This scalable parallel architecture makes the present invention particularly suited to large, complex facilities such as corporate office parks with multiple buildings and data centers, cloud computing facilities with multiple server halls, or mixed-use developments combining residential, commercial, and data center components. By consolidating thermal management infrastructure and enabling coordinated control across multiple facilities or zones, the system achieves superior energy efficiency, reduced capital costs, and enhanced operational flexibility compared to deploying separate, independent HVAC systems for each facility or zone.

It is contemplated that any embodiment discussed in this specification can be implemented with respect to any method of the invention, and vice versa. It will be also understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference. Incorporation by reference is limited such that no subject matter is incorporated that is contrary to the explicit disclosure herein, no claims included in the documents are incorporated by reference herein, and any definitions provided in the documents are not incorporated by reference herein unless expressly included herein.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. In embodiments of any of the compositions and methods provided herein, “comprising” may be replaced with “consisting essentially of” or “consisting of”. As used herein, the phrase “consisting essentially of” requires the specified integer(s) or steps as well as those that do not materially affect the character or function of the claimed invention. As used herein, the term “consisting” is used to indicate the presence of the recited integer (e.g., a feature, an element, a characteristic, a property, a method/process step or a limitation) or group of integers (e.g., feature(s), element(s), characteristic(s), propertie(s), method/process steps or limitation(s)) only.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about”, “substantial” or “substantially” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skilled in the art recognize the modified feature as still having the required characteristics and capabilities of the unmodified feature. In general, but subject to the preceding discussion, a numerical value herein that is modified by a word of approximation such as “about” may vary from the stated value by at least ±1, 2, 3, 4, 5, 6, 7, 10, 12, 15, 20 or 25%.

All of the devices and/or methods disclosed and claimed herein can be made and executed without undue experimentation in light of the present disclosure. While the devices and methods of this invention have been described in terms of preferred embodiments, it will be apparent to those of skill in the art that variations may be applied to the devices and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

What is claimed is:

1. A combined heating and cooling system for a residential area and a data center, the system comprising:
a common liquid circulation loop;
a first heat-exchange unit configured to exchange heat between the liquid and air of the residential area;
a second heat-exchange unit configured to exchange heat between the liquid and at least one of air and electronic equipment of the data center;
a refrigeration unit configured to reduce a temperature of the liquid on the common liquid circulation loop;
a plurality of valves and pipes configured to direct the liquid sequentially through the first heat-exchange unit and the second heat-exchange unit; and
a controller operatively coupled to the valves and configured to operate the valves so that:
in a cooling mode, the liquid cooled by the refrigeration unit is circulated through the first heat-exchange unit to cool the residential area and then through the second heat-exchange unit to cool the data center; and
in a heating mode, heat extracted from the data center by the second heat-exchange unit is transferred via the liquid to the first heat-exchange unit to heat the residential area.

2. The system of claim 1, further comprising a heating unit configured to increase a temperature of the liquid on the common liquid circulation loop, wherein the controller is configured to operate the heating unit when heat extracted from the data center is insufficient to satisfy a heating demand of the residential area.

3. The system of claim 1, further comprising an external heat exchanger located outside a building enclosing at least one of the residential area and the data center, the external heat exchanger being configured to transfer heat between the liquid on the common liquid circulation loop and ambient air, and the controller being configured to selectively route the liquid through the external heat exchanger prior to the refrigeration unit to pre-cool the liquid when a temperature of the ambient air is below a temperature of the liquid.

4. The system of claim 1, wherein the second heat-exchange unit comprises:
a data center air handling unit configured to exchange heat between the liquid and data center air; and
a coolant distribution unit (CDU) configured to exchange heat between the liquid on a facility side and a coolant on an equipment side, the coolant being circulated proximate to electronic equipment of the data center.

5. The system of claim 1, wherein the first heat-exchange unit is a residential air handling unit in fluid communication with air of at least one of an office building, a commercial establishment, or a residential apartment building, the data center being located within the same building or in a basement of the building.

6. The system of claim 1, further comprising temperature sensors disposed at a plurality of locations along the common liquid circulation loop and a flow sensor associated with at least one of the first heat-exchange unit and the second heat-exchange unit, wherein the controller is configured to operate the valves responsive to signals from the temperature sensors and the flow sensor.

7. The system of claim 1, wherein the controller is configured to operate the valves in a summer configuration in which the refrigeration unit is active, the heating unit is inactive, and a common liquid circulation loop is established such that either
i. liquid from an outlet of the refrigeration unit is directed to exchange heat with the residential area via the first heat-exchange unit and then to exchange heat with the data center via the second heat-exchange unit before returning toward an inlet of at least one of the external heat exchanger and the refrigeration unit, or
ii. thermally coupled liquid circuits are operated so that liquid cooled by the refrigeration unit in a primary circuit transfers heat to a secondary circuit serving the first heat-exchange unit and the second heat-exchange unit in series and returns, directly or indirectly, toward the inlet of at least one of the external heat exchanger and the refrigeration unit.

8. The system of claim 1, wherein the controller is configured to operate the valves in a winter configuration in which a common liquid circulation loop is established such that
i. liquid is caused to exchange heat first with the data center via the second heat-exchange unit to extract heat from the data center,
ii. the heating unit is actuated only when a temperature of the liquid after heat exchange at the second heat-exchange unit falls below a heating threshold, and
iii. the liquid is then caused to exchange heat with the residential area via the first heat-exchange unit to transfer heat into air of the residential area,
wherein the common liquid circulation loop is implemented either as a single circuit in which the same liquid sequentially flows through the second and first heat-exchange units or as thermally coupled liquid circuits in which heat is transferred between hydraulically separate circuits while maintaining the overall temperature profile between the second and first heat-exchange units.

9. The system of claim 1, wherein the controller is configured, during the cooling mode, to respond to a condition in which a flow of liquid required by the residential area exceeds a flow required by the data center by:
operating at least one valve to route excess liquid from the first heat-exchange unit directly toward at least one of the external heat exchanger and the refrigeration unit while bypassing at least a portion of the second heat-exchange unit.

10. The system of claim 1, wherein the controller is configured, during the cooling mode, to respond to a condition in which the flow of liquid required by the data center exceeds the flow provided by the first heat-exchange unit by:
operating at least one valve to introduce supplemental liquid from a discharge of the refrigeration unit toward the second heat-exchange unit while bypassing the first heat-exchange unit.

11. The system of claim 4, wherein the controller is configured, during the cooling mode, to respond to a condition in which the flow of liquid required by the data center air handling unit exceeds a flow permissible through the coolant distribution unit by:
operating at least one valve to route a portion of the liquid from the data center air handling unit directly toward at least one of the external heat exchanger and the refrigeration unit while bypassing the coolant distribution unit.

12. The system of claim 3, wherein the controller is configured to:
operate the valves to route liquid from the second heat-exchange unit through the external heat exchanger and then back to an inlet of the second heat-exchange unit to provide free cooling to the data center when the ambient air temperature is sufficiently low to satisfy a data center cooling load; and
concurrently operate the refrigeration unit and the first heat-exchange unit to satisfy a residential cooling load that is not satisfied by the ambient air temperature.

13. A method of cooling a residential area and a data center using a common liquid circulation loop, the method comprising:
cooling a liquid using a refrigeration unit to a first temperature; in a summer configuration, establishing the common liquid circulation loop such that either
i. the liquid is circulated from the refrigeration unit through a first heat-exchange unit to cool air of the residential area and thereby increase the temperature of the liquid to a second temperature, and then circulated from the first heat-exchange unit through a second heat-exchange unit to cool at least one of air and electronic equipment of the data center and thereby increase the temperature of the liquid to a third temperature higher than the second temperature, or
ii. liquid cooled by the refrigeration unit in a primary circuit transfers heat across a common heat exchanger to liquid in a secondary circuit that is circulated sequentially through the first and second heat-exchange units to produce corresponding second and third temperatures; and
returning, directly or indirectly, liquid that has passed through the second heat-exchange unit toward the refrigeration unit.

14. The method of claim 13, further comprising:
routing the liquid from the second heat-exchange unit through an external heat exchanger that exchanges heat with ambient air to reduce the temperature of the liquid when the ambient air temperature is below the third temperature; and
operating the refrigeration unit with a duty cycle that is reduced in response to heat removal performed by the external heat exchanger.

15. The method of claim 13, further comprising:
sensing at least one of liquid temperature and liquid flow rate associated with each of the first and second heat-exchange units; and
based on the sensed at least one of liquid temperature and liquid flow rate, adjusting positions of a plurality of valves to:
bypass at least a portion of the second heat-exchange unit when a flow demand of the residential area exceeds a flow demand of the data center; or
introduce supplemental liquid from a discharge of the refrigeration unit into the second heat-exchange unit when the flow demand of the data center exceeds a flow provided by the first heat-exchange unit.

16. A method of heating a residential area using waste heat from a data center, the method comprising:
circulating a liquid along a common liquid circulation loop;
directing the liquid through a data center heat-exchange unit to extract heat from at least one of air and electronic equipment of the data center and thereby increase a temperature of the liquid to a first elevated temperature;
comparing the first elevated temperature to a heating threshold;
when the first elevated temperature is below the heating threshold, actuating a heating unit to further heat the liquid to a second elevated temperature;
directing the liquid at at least one of the first elevated temperature and the second elevated temperature through a residential heat-exchange unit to transfer heat into air or water of the residential area; and
returning the liquid from the residential heat-exchange unit toward the data center heat-exchange unit.

17. The method of claim 16, further comprising:
sensing at least one of an ambient air temperature and a temperature of the liquid downstream of the residential heat-exchange unit;
when the temperature of the liquid downstream of the residential heat-exchange unit is higher than a cooling threshold, directing the liquid through an external heat exchanger that exchanges heat with ambient air to reduce the temperature of the liquid prior to entering the data center heat-exchange unit.

18. A method of controlling a combined residential and data center heating and cooling system, comprising:
providing a common liquid circulation loop, a refrigeration unit, a heating unit, a first heat-exchange unit associated with a residential area, a second heat-exchange unit associated with a data center, an external heat exchanger, and a plurality of valves;
receiving at a controller at least one of:
a calendar date; and
sensor data indicative of at least one of ambient air temperature, residential load, and data center load;
determining, based on the at least one of the calendar date and the sensor data, whether the system is to be operated in a summer mode or a winter mode; and
automatically actuating the plurality of valves, and at least one of the refrigeration unit and the heating unit, to establish a flow configuration corresponding to the determined one of the summer mode and the winter mode.

19. A data center cooling apparatus comprising:
a data center air handling unit (AHU) configured to exchange heat between a liquid and data center air;
a coolant distribution unit (CDU) configured to exchange heat between the liquid and electronic equipment of the data center;
a liquid circulation path fluidly connecting an outlet of the AHU to an inlet of the CDU such that the liquid flows sequentially from the AHU to the CDU;
a refrigeration unit configured to reduce a temperature of the liquid circulated to at least one of the AHU and the CDU;
an external heat exchanger configured to transfer heat between the liquid and ambient air; and
a valve network configured to selectively bypass at least a portion of one of the AHU and the CDU when a flow demand of the other unit exceeds a predetermined threshold, and further configured to selectively route the liquid through the external heat exchanger prior to the refrigeration unit, thereby accommodating different heat-exchange requirements, flow rates, and heat-rejection modes for the AHU and the CDU.

20. The apparatus of claim 19, wherein the AHU, the CDU, the liquid circulation path, the refrigeration unit, the external heat exchanger, and the valve network form a data center portion of a combined residential and data center heating and cooling system that shares a common liquid circulation loop with a residential heat-exchange unit.
